(19) United States
(12) Patent Application Publication
(10) Pub. No.: US 2015/0185576 A1
(43) Pub. Date: Jul. 2, 2015

(54) Active Device Substrate and Display Panel Using The Same

(71) Applicant: AU Optronics Corporation, HSIN-CHU (TW)

(72) Inventors: Yu-Chin CHU, HSIN-CHU (TW); Sheng-Wen CHENG, HSIN-CHU (TW)

(21) Appl. No.: 14/326,587

(22) Filed: Jul. 9, 2014

(30) Foreign Application Priority Data
Dec. 27, 2013 (TW) 102148725

(51) Int. Cl. G02F 1/1362; G02F 1/1368; H01L 27/12

(52) U.S. Cl. CPC G02F 1/136286; H01L 27/124; G02F 1/1368; G02F 1/136209; G02F 2001/136222

(57) ABSTRACT

An active device substrate includes scan lines, data lines, a first pixel electrode, a second pixel electrode, a first transistor, and a second transistor. The (M−1)th scan line, the (M)th scan line, the (N−1)th data line, and the (N)th data line define a first sub-pixel area. The (L)th scan line, the (L+1)th scan line, the (N)th data line, and the (N+1)th data line define a second sub-pixel area. The first pixel electrode, the first transistor, and the second transistor are disposed in the first sub-pixel area, and at least one portion of the second pixel electrode is disposed in the second sub-pixel area. The first transistor is electrically connected to one of the scan lines, one of the data lines, and the first pixel electrode. The second transistor is electrically connected to one of the scan lines, one of the data lines, and the second pixel electrode.

### RELATED APPLICATIONS

This application claims priority to Taiwan Application Serial Number 102148725, filed Dec. 27, 2013, which is herein incorporated by reference.

### BACKGROUND

1. Field of Invention

The present invention relates to an active device substrate.

2. Description of Related Art

With the advancement of technology, users have more requirements for display panels. Slim-sized, high display quality, and energy saving are main development trends for the display panels. In general, liquid crystal molecules of a display panel may be interfered by the transistors in pixel units to result in light leaks. A black matrix may be used to block the light leakage area so as to improve display quality of the display panel. However, the black matrix reduces the aperture ratio of the display panel, thus adversely increasing energy consumption of the display panel. Therefore, those in the industry are striving to increase the aperture ratio of the display panel while the light leakage area is blocked.

### SUMMARY

An aspect of the present invention is to provide an active device substrate including scan lines, data lines, a first pixel electrode, a second pixel electrode, a first transistor, and a second transistor. The data lines are interlaced with the scan lines. The (M−1)th scan line, the (M)th scan line, the (N−1)th data line, and the (N)th data line define a first sub-pixel area, and the (L)th scan line, the (L+1)th scan line, the (N)th data line, and the (N+1)th data line define a second sub-pixel area, wherein M, N, and L are integers greater than 1. A first distance is formed between the (N−1)th data line and the (N)th data line, and a second distance is formed between the (N)th data line and the (N+1)th data line. The first distance is longer than the second distance. The first pixel electrode is disposed in the first sub-pixel area. At least one portion of the second pixel electrode is disposed in the second sub-pixel area. The first transistor is disposed in the first sub-pixel area and is electrically connected to one of the scan lines, one of the data lines, and the first pixel electrode. The second transistor is disposed in the first sub-pixel area and is electrically connected to one of the scan lines, one of the data lines, and the second pixel electrode.

Another aspect of the present invention is to provide a display panel including the active device substrate, an opposite substrate, and a liquid crystal layer. The opposite substrate is disposed opposite to the active device substrate. The liquid crystal layer is disposed between the active device substrate and the opposite substrate.

### BRIEF DESCRIPTION OF THE DRAWINGS

FIG. 1 is a side view of a display panel according to one embodiment of the present invention;

FIG. 2 is a localized top view of a active device substrate of FIG. 1 according to one embodiment;

FIG. 3 is a localized top view of the display panel of FIG. 1 according to one embodiment;

FIG. 4 is a localized top view of the display panel of FIG. 1 according to another embodiment;

FIG. 5 is a cross-sectional view taken along line 5-5 in FIG. 2;

FIG. 6 is a localized top view of the active device substrate of FIG. 1 according to another embodiment;

FIG. 7A is a cross sectional view taken along line 7A-7A of FIG. 6;

FIG. 7B is a cross sectional view taken along line 7B-7B of FIG. 6;

FIG. 8 is a localized top view of the display panel of FIG. 1 according to another embodiment;

FIG. 9 is a localized top view of the display panel of FIG. 1 according to yet another embodiment;

FIGS. 10 to 13 are localized top views of the display panel of FIG. 1 according to yet other embodiments;

FIGS. 14 and 15 are localized top views of the display panel of FIG. 1 according to yet other embodiments; and

FIGS. 16 and 17 are localized top views of the display panel of FIG. 1 according to yet other embodiments.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

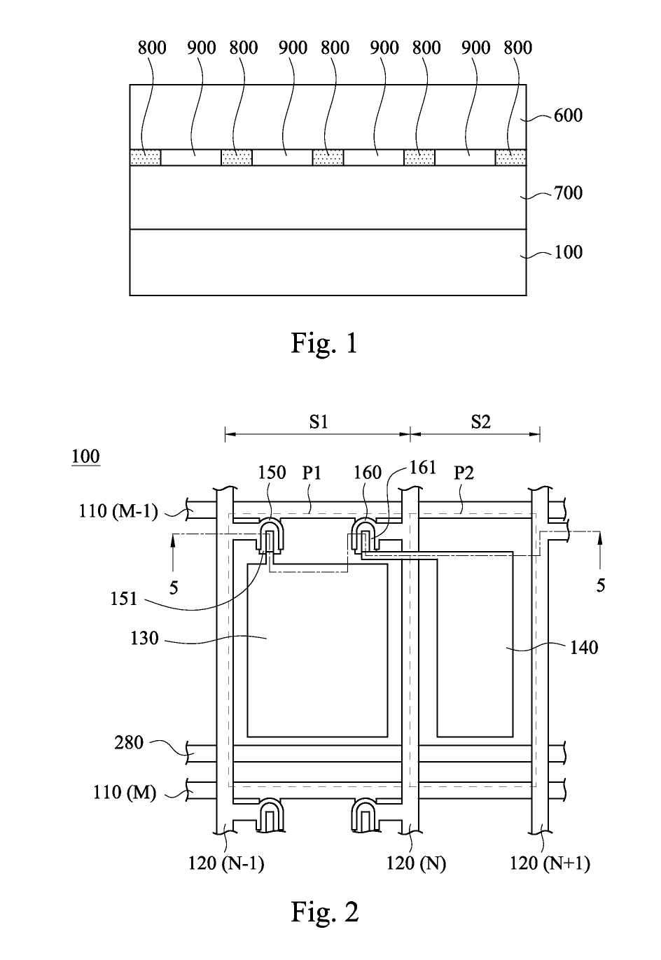

FIG. 1 is a side view of a display panel according to one embodiment of the present invention. The display panel includes an active device substrate 100, an opposite substrate 600, and a liquid crystal layer 700. The opposite substrate 600 is disposed opposite to the active device substrate 100. The liquid crystal layer 700 is disposed between the active device substrate 100 and the opposite substrate 600.

Reference is made to FIG. 2 which is a localized top view of the active device substrate 100 of FIG. 1 according to one embodiment. As shown in FIG. 2, the active device substrate 100 includes scan lines 110, data lines 120, a first pixel electrode 130, a second pixel electrode 140, a first transistor 150, and a second transistor 160. The data lines 120 are interlaced with the scan lines 110. The (M−1)th scan line 110, the (M)th scan line 110, the (N−1)th data line 120, and the (N)th data line 120 define a first sub-pixel area P1, and the (L)th scan line 110, the (L+1)th scan line 110, the (N)th data line 120, and the (N+1)th data line 120 define a second sub-pixel area P2, where M, N, and L are integers greater than one. In this embodiment, L=M−1, i.e., the (L)th scan line 110 is the (M−1)th scan line 110, and the (L+1)th scan line 110 is the (M)th scan line 110. For clarity, in FIG. 2, the scan lines 110 are marked with M.

A first distance S1 is formed between the (N−1)th data line 120 and the (N)th data line 120, and a second distance S2 is formed between the (N)th data line 120 and the (N+1)th data line 120. The first distance S1 is longer than the second distance S2 as shown in the embodiment of FIG. 2. The first pixel electrode 130 is disposed in the first sub-pixel area P1. At least one portion of the second pixel electrode 140 is disposed in the second sub-pixel area P2. The first transistor 150 is disposed in the first sub-pixel area P1 and is electrically connected to one of the scan lines 110, one of the data lines 120, and the first pixel electrode 130. In this embodiment, the first transistor 150 is electrically connected to the (M−1)th scan lines 110, the (N−1)th data lines 120, and the first pixel electrode 130. The second transistor 160 is disposed in the first sub-pixel area P1 and is electrically connected to one of the scan lines 110, one of the data lines 120, and the second pixel electrode 140. In this embodiment, the second transistor 160 is electrically connected to the (L, i.e., M−1)th scan lines 110, the (N) the data lines 120, and the second pixel electrode 140. It is noted that even through there are only two scan lines 110 and three data lines 120 in FIG. 2, the numbers of the scan lines 110 and the data lines 120 are not limited thereto. A person having ordinary skill in the art may choose suitable numbers of the scan lines 110 and the data lines 120 according to actual requirements.

In this embodiment, the first transistor 150 is configured for driving the first pixel electrode 130, and the second transistor 160 is configured for driving the second pixel electrode 140. Since both of the first transistor 150 and the second transistor 160 are disposed in the first sub-pixel area P1, there is no transistor in the second sub-pixel area P2. Accordingly, liquid crystal materials in the liquid crystal layer 700 (see FIG. 1) above the second sub-pixel area P2 is not disturbed by transistors, and the aperture ratio of the second sub-pixel area P2 of the active device substrate 100 can be increased.

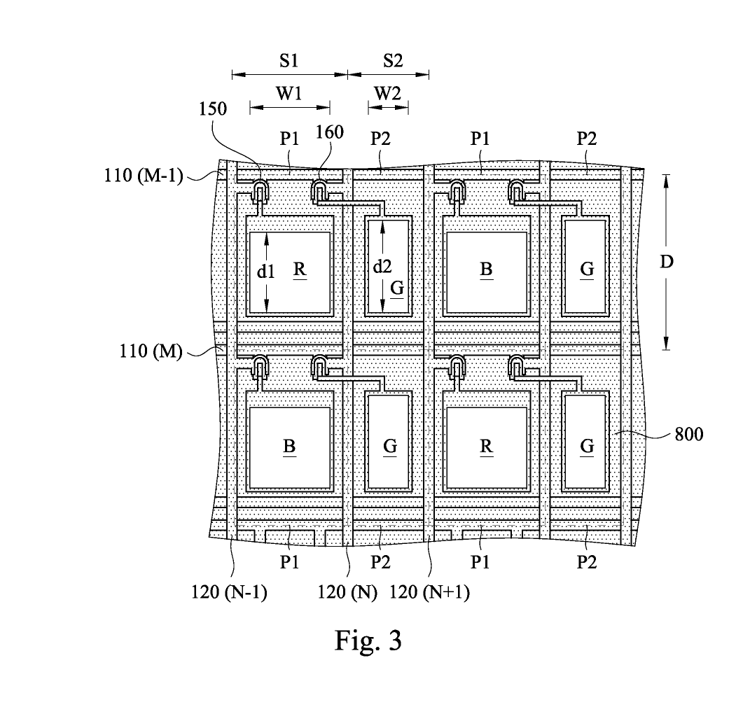

In greater detail, reference is made to FIGS. 1 and 3, where FIG. 3 is a localized top view of the display panel of FIG. 1 according to one embodiment. In this embodiment, the active device substrate 100 has the first sub-pixel areas P1 and the second sub-pixel areas P2 alternately arranged with the first sub-pixel areas P1 along an extension direction of the data line 120. The display panel may further include a black matrix 800 disposed between the opposite substrate 600 and the liquid crystal layer 700. A projection of the black matrix 800 on the active device substrate 100 covers at least the first transistor 150, the second transistor 160, the scan lines 110, and the data lines 120. It is noted that, for clarity, the black matrix 800 in FIG. 3 is indicated by dots, and the elements below the black matrix 800 are patterned with solid lines.

Since the first transistor 150 and the second transistor 160 may affect the orientations of the liquid crystal molecules and cause light leakage of the display panel, the black matrix 800 is used to cover the first transistor 150 and the second transistor 160 to improve the light leakage problem. In this embodiment, since there is no transistor within the second sub-pixel area P2, the coverage area of the black matrix 800 in the second sub-pixel area P2 can be reduced, and the aperture ratio of the second sub-pixel area P2 can be increased.

For example, a distance D formed between the (M−1)th scan line 110 and (M)th scan line 110 is 60 μm, and the second distance S2 is 21.2 μm. Hence, the area of the second sub-pixel area P2 is D×S2=1272 μm². The black matrix 800 exposes a portion of the second sub-pixel area P2, and the exposed portion of the second sub-pixel area P2 has a length d2=34.5 μm and a width W2=15.21 μm, such that the exposed area is d2×W2=524.75 μm². Hence, the aperture ratio of the second sub-pixel area P2 is:

(d2×W2)/(D×S2)=41.23%, which is 6.31% higher than that of a conventional pixel structure.

Moreover, the first distance S1 is 38.8 μm. Hence, the area of the first sub-pixel area P1 is D×S1=2328 μm². The black matrix 800 exposes a portion of the first sub-pixel area P1, and the exposed portion of the first sub-pixel area P1 has a length d1=32 μm and a width W1=32.79 μm, such that the exposed area is d1×W1=1049.28 μm². Hence, the aperture ratio of the first sub-pixel area P1 is:

(d1×W1)/(D×S1)=45.08%, which is 0.38% higher than that of the conventional pixel structure. In other words, the structure of the present embodiment increases the whole aperture ratio of the active device substrate 100.

In this embodiment, the first distance S1 can be further shorter than or equal to twice of the second distance S2. Such structure can be applied in an active device substrate by using a Sub Pixel Rendering (SPR) technology. In greater detail, the SPR technology reduces the number of sub-pixels by sharing sub-pixels between two adjacent pixels. In this manner, the active device substrate achieves the effect of using low resolution to simulate high resolution, and increases the aperture ratio. Also, lower energy consumption is needed for achieving the same brightness, thereby promoting the battery life.

Reference is made again to FIGS. 1 and 3. The display panel may further include a filter layer 900 disposed between the opposite substrate 600 and the liquid crystal layer 700. The filter layer 900 includes red filtering portions R, blue filtering portions B, and green filtering portions G. The position of the filter layer 900 is compliment with that of the black matrix 800. Projections of the red filtering portions R on the active device substrate 100 fall within portions of the first sub-pixel areas P1, and projections of the blue filtering portions B on the active device substrate 100 fall within other portions of the first sub-pixel areas P1, and projections of the green filtering portions G on the active device substrate 100 fall within the second sub-pixel areas P2. In the embodiment of FIG. 3, the filtering portions are the red filtering portion R, the green filtering portion G, the blue filtering portion B, and the green filtering portion G arranged in sequence from the upper left to the upper right of the figure; and the filtering portions are the blue filtering portion B, the green filtering portion G, the red filtering portion R, and the green filtering portion G arranged from the lower left to the lower right. The area shown in FIG. 3 can represent a single pixel unit of a SPR substrate. In addition, since the area of the first sub-pixel area P1 in FIG. 3 is larger than that of the second sub-pixel area P2, the brightness of the second sub-pixel area P2 can be higher than that of the first sub-pixel area P1. That is, the brightness of green light is higher than that of red light and blue light in this embodiment.

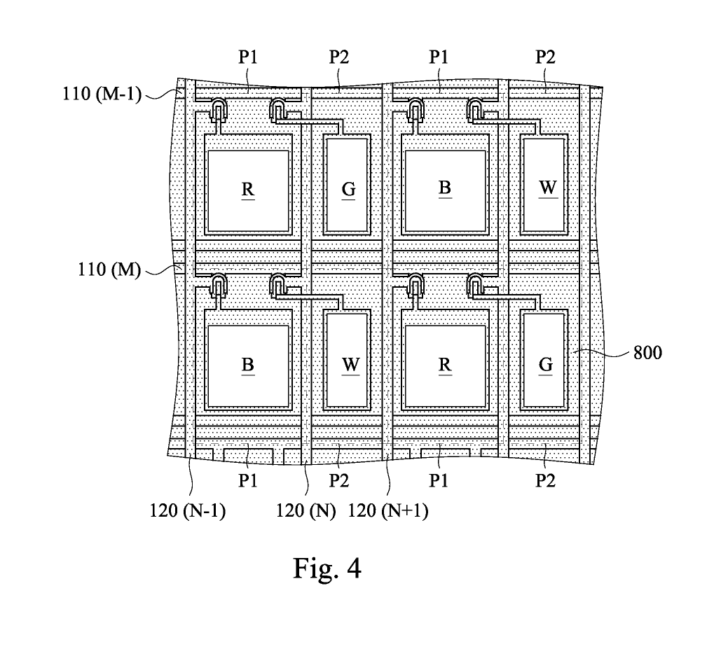

Reference is made to FIG. 4 which is a localized top view of the display panel of FIG. 1 according to another embodiment. The difference between the present embodiment and the embodiment of FIG. 3 pertains to the arrangement and the types of the filtering portions of the filter layer 900 (see FIG. 1). In this embodiment, the filter layer 900 further includes white filtering portions W. The projections of the red filtering portions R on the active device substrate 100 fall within portions of the first sub-pixel areas P1, and the projections of the blue filtering portions B on the active device substrate 100 fall within other portions of the first sub-pixel areas P1, and the projections of the green filtering portions G on the active device substrate 100 fall within portions of the second sub-pixel areas P2, and projections of the white filtering portions W on the active device substrate 100 fall within other portions of the second sub-pixel areas P2. In the embodiment of FIG. 4, the filtering portions are the red filtering portion R, the green filtering portion G, the blue filtering portion B, and the white filtering portion W arranged in sequence from the upper left to the upper right of the figure; and the filtering portions are the blue filtering portion B, the white filtering portion W, the red filtering portion R, and the green filtering portion G arranged from the lower left to the lower right. The area shown in FIG. 4 may represent a single pixel unit of a SPR substrate. In addition, the brightness of the green light and white light are higher than that of the red light and the blue light in this embodiment. Other features of this embodiment are the same as those of the embodiment of FIG. 3, and therefore, description in this regard will not be provided hereinafter.

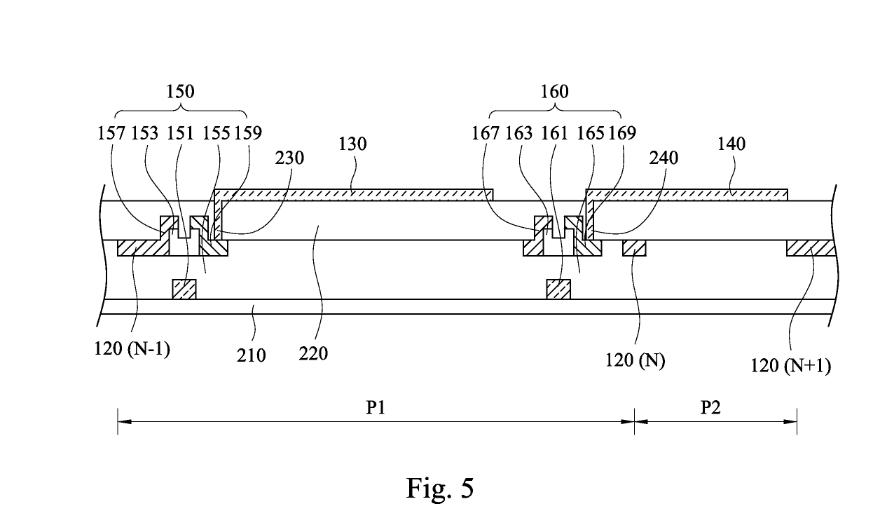

FIG. 5 is a cross-sectional view taken along line 5-5 in FIG. 2. Reference is made to FIGS. 2 and 5. In this embodiment, the active device substrate 100 can further includes a base 210, a first passivation layer 220, a first plug 230, and a second plug 240. The scan lines 110, the data lines 120, the first transistor 150, and the second transistor 160 are all disposed on the base 210. The first passivation layer 220 covers the first transistor 150, the second transistor 160, the scan lines 110, and the data lines 120. The first pixel electrode 130 and the second pixel electrode 140 are disposed on the first passivation layer 220. The first plug 230 passes through at least the first passivation layer 220 and is electrically connected to the first pixel electrode 130 and the first transistor 150. The second plug 240 passes through at least the first passivation layer 220 and is electrically connected to the second pixel electrode 140 and the second transistor 160.

In greater detail, the first transistor 150 may include a first gate electrode 151, a first channel layer 153, a gate dielectric layer 155, a first source electrode 157, and a first drain electrode 159. The first gate electrode 151 is electrically connected to the one of the scan lines 110. For example, the first gate electrode 151 is electrically connected to the (M−1)th scan line 110 as shown in FIG. 2 in this embodiment. The first channel layer 153 is disposed above the first gate electrode 151. The gate dielectric layer 155 is disposed at least between the first gate electrode 151 and the first channel layer 153. The first source electrode 157 is electrically connected to the (N−1)th data line 120 and the first channel layer 153. The first drain electrode 157 is separated from the first source electrode 157, and is electrically connected to the first channel layer 153, and is electrically connected to the first pixel electrode 130 through the first plug 230. Accordingly, the first transistor 150 can provide voltage to the first pixel electrode 130 by applying current to the (M−1)th scan line 110 and the (N−1)th data line 120.

Moreover, the second transistor 160 may include a second gate electrode 161, a second channel layer 163, a gate dielectric layer 165, a second source electrode 167, and a second drain electrode 169. The second gate electrode 161 is electrically connected to the one of the scan lines 110. For example, the second gate electrode 161 is electrically connected to the (L, i.e., M−1)th scan line 110 as shown in FIG. 2 in this embodiment. The second channel layer 163 is disposed above the second gate electrode 161. The gate dielectric layer 165 is disposed at least between the second gate electrode 161 and the second channel layer 163. The gate dielectric layer 165 and the gate dielectric layer 155 can be integrally formed. The second source electrode 167 is electrically connected to the (N)th data line 120 and the second channel layer 163. The second drain electrode 169 is separated from the second source electrode 167, and is electrically connected to the second channel layer 163, and is electrically connected to the second pixel electrode 140 through the second plug 240. Accordingly, the second transistor 160 can provide voltage to the second pixel electrode 140 by applying current to the (L, i.e., M−1)th scan line 110 and the (N)th data line 120.

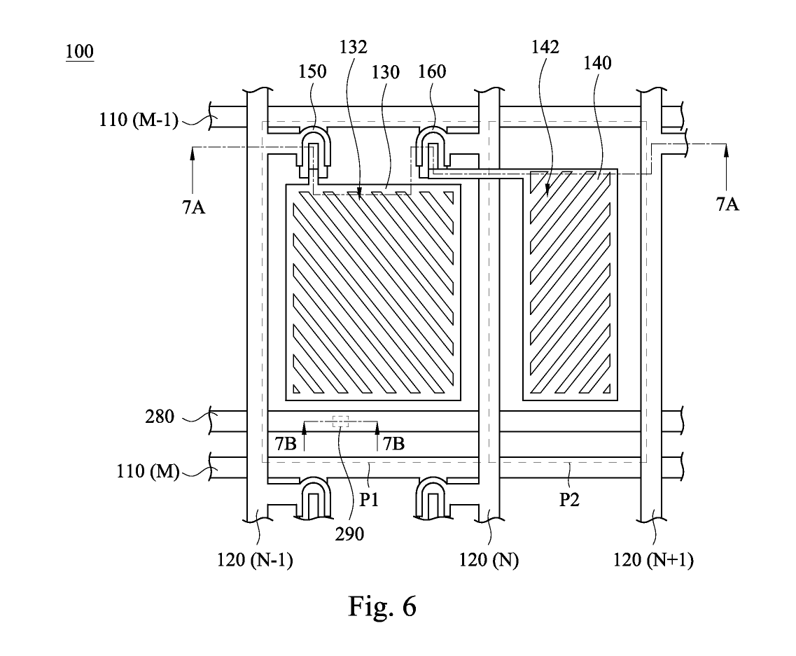

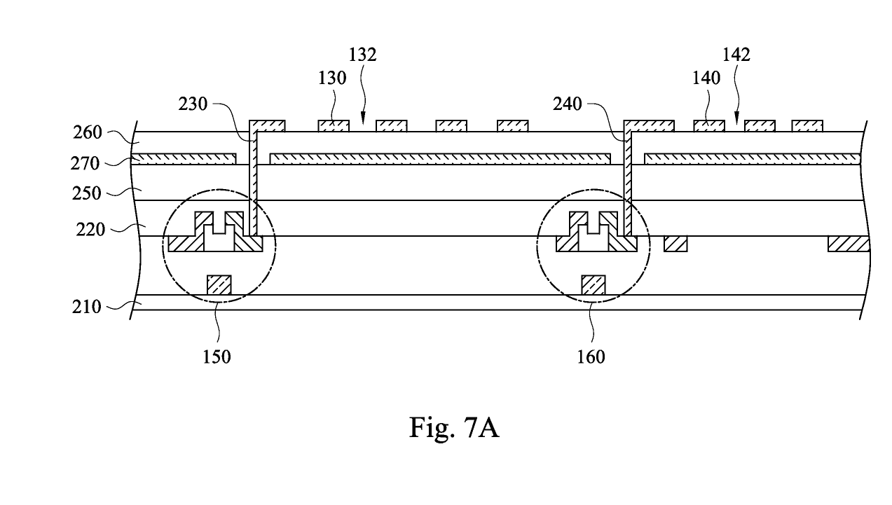

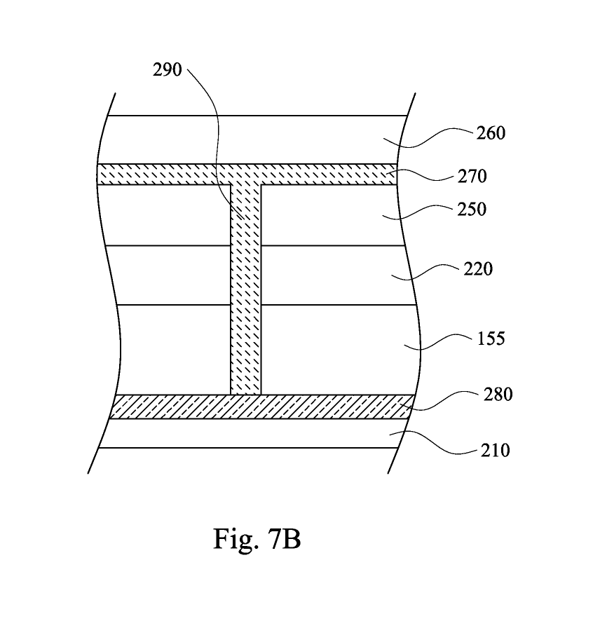

However, the active device substrate 100 is not limited to the structure mentioned above. FIG. 6 is a localized top view of the active device substrate 100 of FIG. 1 according to another embodiment, and FIG. 7A is a cross sectional view taken along line 7A-7A of FIG. 6. The difference between the present embodiment and the embodiment of FIG. 5 pertains to the configurations between the first passivation layer 220 and the first pixel electrode 130 and between the first passivation layer 220 and the second pixel electrode 140. In this embodiment, the active device substrate 100 may further include an insulating layer 250, a second passivation layer 260, and a transparent conductive layer 270. The insulating layer 250 is disposed between the first passivation layer 220 and the first pixel electrode 130 and between the first passivation layer 220 and the second pixel electrode 140. The second passivation layer 260 is disposed between the insulating layer 250 and the first pixel electrode 130 and between the insulating layer 250 and the second pixel electrode 140. The first plug 230 and the second plug 240 further pass through the insulating layer 250 and the second passivation layer 260. The transparent conductive layer 270 is disposed between the insulating layer 250 and the second passivation layer 260, and the transparent conductive layer 270 is electrically insulated from the first plug 230 and the second plug 240.

FIG. 7B is a cross sectional view taken along line 7B-7B of FIG. 6. In greater detail, reference is made to FIGS. 6 and 7B. The active device substrate 100 may further include common electrodes 280 and third plugs 290. The common electrodes 280 are disposed between the base 210 and the first passivation layer 220. More specifically, the common electrodes 280 are disposed between the base 210 and the gate dielectric layer 155 (and 165). The common electrodes 280 are disposed alternately with the scan lines 110. The third plugs 290 pass through at least the first passivation layer 220 and the insulating layer 250, and are electrically connected to the common electrodes 280 and the transparent conductive layer 270. Accordingly, the transparent conductive layer 270 that is electrically connected to the common electrode 280 has a common voltage by applying current to the common electrode 280.

Reference is made to FIGS. 6 and 7A again. In this embodiment, the first pixel electrode 130 and the second pixel electrode 140 have strip-shaped openings 132 and 142 respectively. By designing the arrangements of the strip-shaped openings 132 and 142 of each pixel electrode, for example, the arrangements of the strip-shaped openings 132 and 142 are different in FIG. 4, the liquid crystal molecules have different orientation to achieve wide viewing angle display.

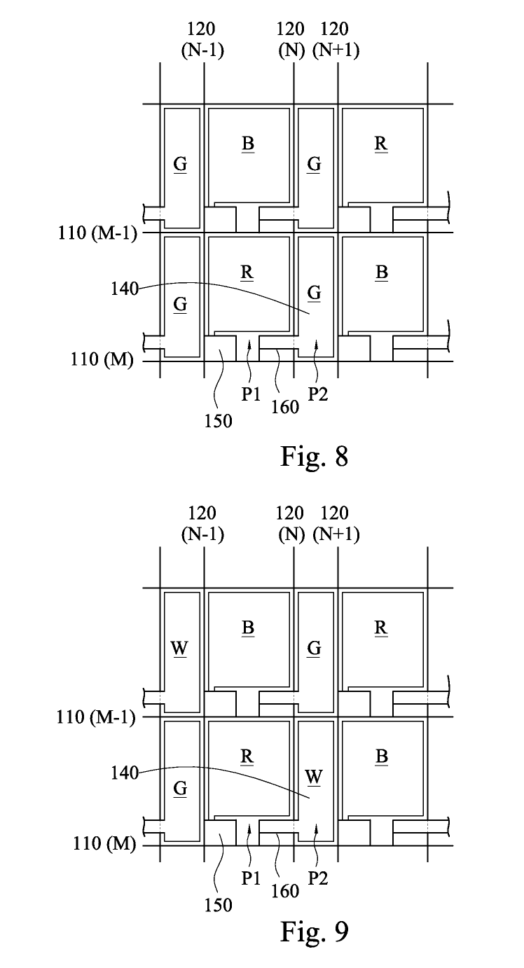

Reference is made to FIG. 8 which is a localized top view of the display panel of FIG. 1 according to another embodiment. For clarity, each filtering portion is indicated by a marker, and the black matrix 800 (see FIG. 3) is omitted in FIGS. 8 to 17. The difference between the present embodiment and the embodiment of FIG. 3 pertains to the electrically connections among the first transistor 150, the second transistor 160, the scan lines 110, and the data lines 120. In this embodiment, the first transistor 150 is electrically connected to the (M)th scan line 110 and the (N−1)th data line 120, and the second transistor 160 is electrically connected to the (L+1, i.e., M)th scan line 110 and the (N)th data line 120. Other features of this embodiment are the same as those of the embodiment of FIG. 3, and therefore, description in this regard will not be provided hereinafter.

Reference is made to FIG. 9 which is a localized top view of the display panel of FIG. 1 according to yet another embodiment. The difference between the present embodiment and the embodiment of FIG. 8 pertains to the present of the white filtering portions W. In this embodiment, the white filtering portions W can be disposed in portions of the second sub-pixel areas P2. Other features of this embodiment are the same as those of the embodiment of FIG. 8, and therefore, description in this regard will not be provided hereinafter.

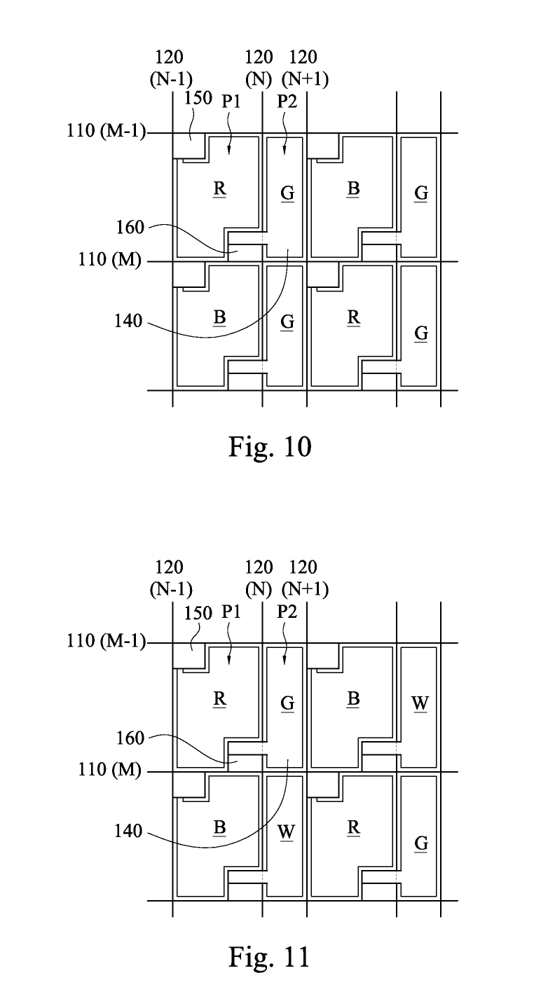

Reference is made to FIGS. 10 to 13 which are localized top views of the display panel of FIG. 1 according to yet other embodiments. In the embodiments of FIGS. 10 to 13, the first transistor 150 and the second transistor 160 in the same first sub-pixel area P1 are electrically connected to different scan lines 110. In FIGS. 10 and 11, the first transistor 150 is electrically connected to the (M−1)th scan line 110 and the (N−1)th data line 120, and the second transistor 160 is electrically connected to the (L+1, i.e., M)th scan line 110 and the (N)th data line 120. In FIG. 10, the filter layer 900 (see FIG. 1) includes the red filtering portions R, the blue filtering portions B, and the green filtering portions G. In FIG. 11, the filter layer 900 includes the red filtering portions R, the blue filtering portions B, the green filtering portions G, and the white filtering portions W.

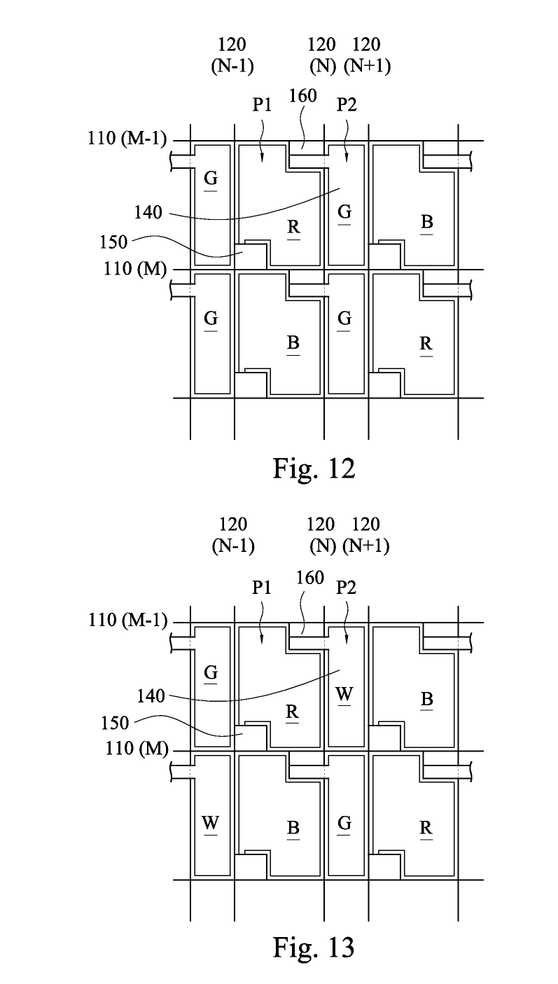

Moreover, in FIGS. 12 and 13, the first transistor 150 is electrically connected to the (M)th scan line 110 and the (N−1)th data line 120, and the second transistor 160 is electrically connected to the (L, i.e., M−1)th scan line 110 and the (N)th data line 120. In FIG. 12, the filter layer 900 includes the red filtering portions R, the blue filtering portions B, and the green filtering portions G. In FIG. 13, the filter layer 900 includes the red filtering portions R, the blue filtering portions B, the green filtering portions G, and the white filtering portions W. Other features of the embodiments of FIGS. 10 and 12 are the same as those of the embodiment of FIG. 3, and other features of the embodiments of FIGS. 11 and 13 are the same as those of the embodiment of FIG. 4, and therefore, description in this regard will not be provided hereinafter.

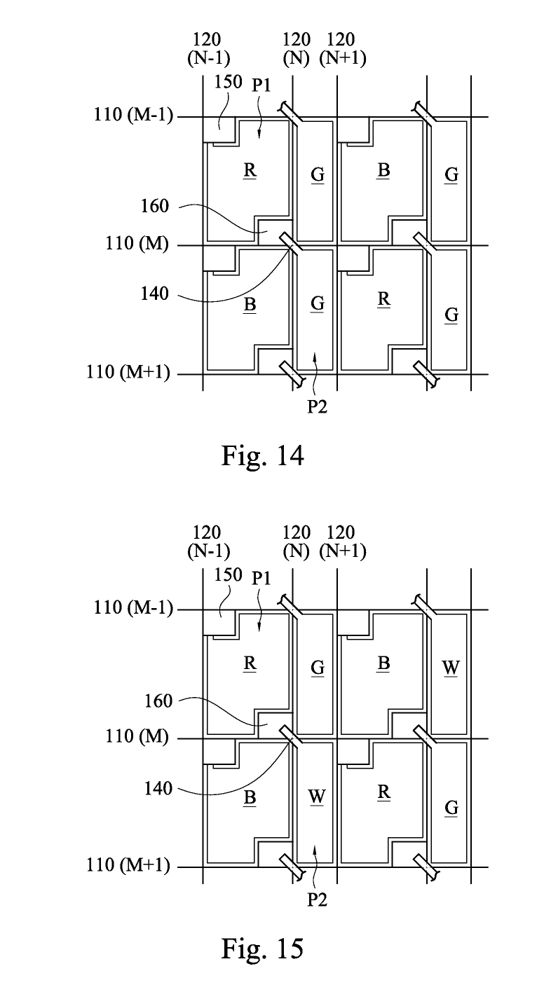

Reference is made to FIGS. 14 and 15 which are localized top views of the display panel of FIG. 1 according to yet other embodiments. In embodiments of FIGS. 14 and 15, L=M, the first transistor 150 is electrically connected to the (M−1)th scan line 110 and the (N−1)th data line 120, and the second transistor 160 is electrically connected to the (L, i.e., M)th scan line 110 and the (N)th data line 120. In FIG. 14, the filter layer 900 (see FIG. 1) includes the red filtering portions R, the blue filtering portions B, and the green filtering portions G. In FIG. 15, the filter layer 900 includes the red filtering portions R, the blue filtering portions B, the green filtering portions G, and the white filtering portions W. Other features of the embodiment of FIG. 14 are the same as those of the embodiment of FIG. 3, and other features of the embodiment of FIG. 15 are the same as those of the embodiment of FIG. 4, and therefore, description in this regard will not be provided hereinafter.

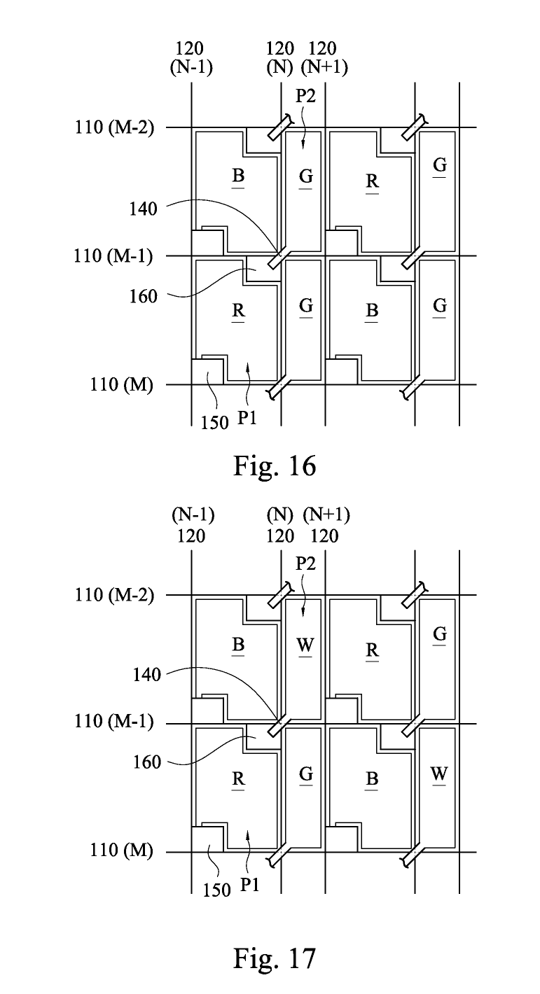

Reference is made to FIGS. 16 and 17 which are localized top views of the display panel of FIG. 1 according to yet other embodiments. In embodiments of FIGS. 16 and 17, L=M−2, the first transistor 150 is electrically connected to the (M)th scan line 110 and the (N−1)th data line 120, and the second transistor 160 is electrically connected to the (L+1, i.e., M−1)th scan line 110 and the (N)th data line 120. In FIG. 16, the filter layer 900 includes the red filtering portions R, the blue filtering portions B, and the green filtering portions G. In FIG. 17, the filter layer 900 includes the red filtering portions R, the blue filtering portions B, the green filtering portions G, and the white filtering portions W. Other features of the embodiment of FIG. 16 are the same as those of the embodiment of FIG. 3, and other features of the embodiment of FIG. 17 are the same as those of the embodiment of FIG. 4, and therefore, description in this regard will not be provided hereinafter.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An active device substrate, comprising:
a plurality of scan lines;
a plurality of data lines interlaced with the scan lines, wherein the (M−1)th scan line, the (M)th scan line, the (N−1)th data line, and the (N)th data line define a first sub-pixel area, and the (L)th scan line, the (L+1)th scan line, the (N)th data line, and the (N+1)th data line define a second sub-pixel area, where M, N, and L are integers greater than 1, and a first distance is formed between the (N−1)th data line and the (N)th data line, and a second distance is formed between the (N)th data line and the (N+1)th data line, and the first distance is longer than the second distance;
a first pixel electrode disposed in the first sub-pixel area;
a second pixel electrode, at least one portion of the second pixel electrode disposed in the second sub-pixel area;
a first transistor disposed in the first sub-pixel area and electrically connected to one of the scan lines, one of the data lines, and the first pixel electrode; and
a second transistor disposed in the first sub-pixel area and electrically connected to one of the scan lines, one of the data lines, and the second pixel electrode.

2. The active device substrate of claim 1, further comprising:
a base, wherein the scan lines, the data lines, the first transistor, and the second transistor are disposed on the base;
a first passivation layer covering the first transistor, the second transistor, the scan lines, and the data lines, and the first pixel electrode and the second pixel electrode are disposed on the first passivation layer;
a first plug passing through at least the first passivation layer and electrically connected to the first pixel electrode and the first transistor; and
a second plug passing through at least the first passivation layer and electrically connected to the second pixel electrode and the second transistor.

3. The active device substrate of claim 2, wherein the first transistor comprises:
a first gate electrode electrically connected to the one of the scan lines;
a first channel layer disposed above the first gate electrode;
a gate dielectric layer disposed at least between the first gate electrode and the first channel layer;
a first source electrode electrically connected to the one of the data lines and the first channel layer; and
a first drain electrode which is separated from the first source electrode, and is electrically connected to the first channel layer, and is electrically connected to the first pixel electrode through the first plug.

4. The active device substrate of claim 2, wherein the second transistor comprises:
a second gate electrode electrically connected to the one of the scan lines;
a second channel layer disposed above the second gate electrode;
a gate dielectric layer disposed at least between the second gate electrode and the second channel layer;
a second source electrode electrically connected to the one of the data lines and the second channel layer; and
a second drain electrode which is separated from the second source electrode, and is electrically connected to the second channel layer, and is electrically connected to the second pixel electrode through the second plug.

5. The active device substrate of claim 2, further comprising:
an insulating layer which is disposed between the first passivation layer and the first pixel electrode and is between the first passivation layer and the second pixel electrode;
a second passivation layer which is disposed between the insulating layer and the first pixel electrode and is between the insulating layer and the second pixel electrode, wherein the first plug and the second plug further pass through the insulating layer and the second passivation layer; and
a transparent conductive layer disposed between the insulating layer and the second passivation layer, and the transparent conductive layer being electrically insulated from the first plug and the second plug.

6. The active device substrate of claim 5, further comprising:
a plurality of common electrodes which are disposed between the base and the first passivation layer, and are disposed alternately with the scan lines; and
a plurality of third plugs passing through at least the first passivation layer and the insulating layer and electrically connected to the common electrodes and the transparent conductive layer.

7. The active device substrate of claim 5, wherein the first pixel electrode and the second pixel electrode both have a plurality of strip-shaped openings respectively.

8. The active device substrate of claim 1, wherein the first distance is further shorter than or equal to twice of the second distance.

9. The active device substrate of claim 1, wherein L=M−1, and the first transistor is electrically connected to the (M−1)th scan line and the (N−1)th data line, and the second transistor is electrically connected to the (L)th scan line and the (N)th data line.

10. The active device substrate of claim 1, wherein L=M−1, and the first transistor is electrically connected to the (M)th scan line and the (N−1)th data line, and the second transistor is electrically connected to the (L+1)th scan line and the (N)th data line.

11. The active device substrate of claim 1, wherein L=M−1, and the first transistor is electrically connected to the (M−1)th scan line and the (N−1)th data line, and the second transistor is electrically connected to the (L+1)th scan line and the (N)th data line.

12. The active device substrate of claim 1, wherein L=M−1, and the first transistor is electrically connected to the (M)th scan line and the (N−1)th data line, and the second transistor is electrically connected to the (L)th scan line and the (N)th data line.

13. The active device substrate of claim 1, wherein L=M, and the first transistor is electrically connected to the (M−1)th scan line and the (N−1)th data line, and the second transistor is electrically connected to the (L)th scan line and the (N)th data line.

14. The active device substrate of claim 1, wherein L=M−2, and the first transistor is electrically connected to the (M)th scan line and the (N−1)th data line, and the second transistor is electrically connected to the (L+1)th scan line and the (N)th data line.

15. A display panel, comprising:
an active device substrate, comprising:
a plurality of scan lines;
a plurality of data lines interlaced with the scan lines, wherein the (M−1)th scan line, the (M)th scan line, the (N−1)th data line, and the (N)th data line define a first sub-pixel area, and the (L)th scan line, the (L+1)th scan line, the (N)th data line, and the (N+1)th data line define a second sub-pixel area, where M, N, and L are integers greater than 1, and a first distance is formed between the (N−1)th data line and the (N)th data line, and a second distance is formed between the (N)th data line and the (N+1)th data line, and the first distance is longer than the second distance;
a first pixel electrode disposed in the first sub-pixel area;
a second pixel electrode, at least one portion of the second pixel electrode disposed in the second sub-pixel area;
a first transistor disposed in the first sub-pixel area and electrically connected to one of the scan lines, one of the data lines, and the first pixel electrode; and
a second transistor disposed in the first sub-pixel area and electrically connected to one of the scan lines, one of the data lines, and the second pixel electrode;
an opposite substrate disposed opposite to the active device substrate; and
a liquid crystal layer disposed between the active device substrate and the opposite substrate.

16. The display panel of claim 15, further comprising:
a filter layer disposed between the opposite substrate and the liquid crystal layer, wherein the filter layer comprises a plurality of red filtering portions, a plurality of blue filtering portions, and a plurality of green filtering portions; and
wherein the first sub-pixel areas and the second sub-pixel areas of the active device substrate are plural, projections of the red filtering portions on the active device substrate are respectively in portions of the first sub-pixel areas, projections of the blue filtering portions on the active device substrate are respectively in another portions of the first sub-pixel areas, and projections of the green filtering portions on the active device substrate are respectively in the second sub-pixel areas.

17. The display panel of claim 15, further comprising:
a filter layer disposed between the opposite substrate and the liquid crystal layer, wherein the filter layer comprises a plurality of red filtering portions, a plurality of blue filtering portions, a plurality of green filtering portions, and a plurality of whit filtering portions; and
wherein there are plural first sub-pixel areas and plural second sub-pixel areas of the active device substrate, projections of the red filtering portions on the active device substrate fall within portions of the first sub-pixel areas, and projections of the blue filtering portions on the active device substrate fall within other portions of the first sub-pixel areas, and projections of the green filtering portions on the active device substrate fall within portions of the second sub-pixel areas, and projections of the white filtering portions on the active device substrate fall within other portions of the second sub-pixel areas.

18. The display panel of claim 15, further comprising:
a black matrix disposed between the opposite substrate and the liquid crystal layer, wherein a projection of the black matrix on the active device substrate covers at least the first transistor, the second transistor, the scan lines, and the data lines.

19. The display panel of claim 15, wherein a brightness of the second sub-pixel area is higher than a brightness of the first sub-pixel area.
